(19) United States
(12) Patent Application Publication
(10) Pub. No.: US 2015/0250075 A1
(43) Pub. Date: Sep. 3, 2015

(54) COOLER AND ELECTRONIC DEVICE

(71) Applicant: FUJITSU LIMITED, Kawasaki-shi (JP)

(72) Inventors: Keita Hirai, Kawasaki (JP); Hitoshi Nori, Kawasaki (JP); Tsuyoshi So, Kawasaki (JP)

(21) Appl. No.: 14/587,261

(22) Filed: Dec. 31, 2014

(30) Foreign Application Priority Data
Feb. 28, 2014 (JP) 2014-037644

(51) Int. Cl. H05K 7/20

(52) U.S. Cl. CPC H05K 7/20254

(57) ABSTRACT

A cooler includes: a casing arranged opposed to a heat releasing surface of a heater element; and a first flow channel which is provided in the casing and through which a refrigerant flows, wherein in a direction orthogonal to the heat releasing surface, a length of the first flow channel on a heat releasing surface side is shorter than a length of the first flow channel on the opposite side to the heat releasing surface.

### CROSS-REFERENCE TO RELATED APPLICATION

This application is based upon and claims the benefit of priority of the prior Japanese Patent Application No. 2014-037644 filed on Feb. 28, 2014, the entire contents of which are incorporated herein by reference.

### FIELD

The embodiments discussed herein are related to a cooler configured to cool a heater element and an electronic device including the cooler.

### BACKGROUND

Conventionally, in order to cool a heater element such as a central processing unit (CPU), a cooler is often placed on the heater element. A cooler includes multiple flow channels which are partitioned by plate-like fins, for example, and through which a refrigerant flows.

There are known coolers such as a cooler configured to generate a turbulent flow in a refrigerant, a cooler having flow channels with flow channel length (that is, length in a refrigerant flow direction) in a center area made short to equally distribute a refrigerant, and a cooler including flow channels with their widths varied in accordance with their flow channel lengths to achieve an equal flow velocity. In addition, there are also known coolers such as a cooler including flow channels, at least one of which includes a fin different in shape from fins in the other flow channels to vary pressure loss among them, and a cooler including flow channels with shapes designed to allow a fluid to flow at a higher speed in a high-temperature area.

The following are reference documents.

[Document 1] International Publication Pamphlet No. WO 2012/114475,

[Document 2] Japanese Laid-open Patent Publication No. 2001-24126,

[Document 3] Japanese Laid-open Patent Publication 2007-333357,

[Document 4] Japanese Laid-open Patent Publication 2011-228566, and

[Document 5] Japanese National Publication of International Patent Application No. 2008-535261.

### SUMMARY

According to an aspect of the invention, a cooler includes: a casing arranged opposed to a heat releasing surface of a heater element; and a first flow channel which is provided in the casing and through which a refrigerant flows, wherein in a direction orthogonal to the heat releasing surface, a length of the first flow channel on a heat releasing surface side is shorter than a length of the first flow channel on the opposite side to the heat releasing surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating an electronic device according to a first embodiment;

FIG. 2 is a cross-sectional view taken along a line II-II in FIG. 1;

FIG. 3 is a cross-sectional view (cross-sectional view taken along a line III-III in FIG. 4) illustrating an internal structure of a cooler according to the first embodiment;

FIG. 4 is a cross sectional view taken along a line IV-IV in FIG. 3;

FIG. 5 is a cross-sectional view taken along a line V-V in FIG. 3;

FIG. 6 is a cross-sectional view taken along a line VI-VI in FIG. 3;

FIG. 7 is a cross-sectional view taken along a line VII-VII in FIG. 4;

FIG. 8 is a cross-sectional view (cross-sectional view taken along a line VIII-VIII in FIG. 9) illustrating an internal structure of a cooler according to a second embodiment;

FIG. 9 is a cross-sectional view taken along a line IX-IX in FIG. 8;

FIG. 10 is a cross-sectional view taken along a line X-X in FIG. 8;

FIG. 11 is a cross-sectional view taken along a line XI-XI in FIG. 8;

FIG. 12 is a cross-sectional view taken along a line XII-XII in FIG. 9;

FIG. 13 is a plan view illustrating an electronic device according to a related technology;

FIG. 14 is a cross-sectional view taken along a line XIV-XIV in FIG. 13; and

FIG. 15 is a plan view of a heater element for illustrating a temperature distribution on a heat releasing surface.

### DESCRIPTION OF EMBODIMENTS

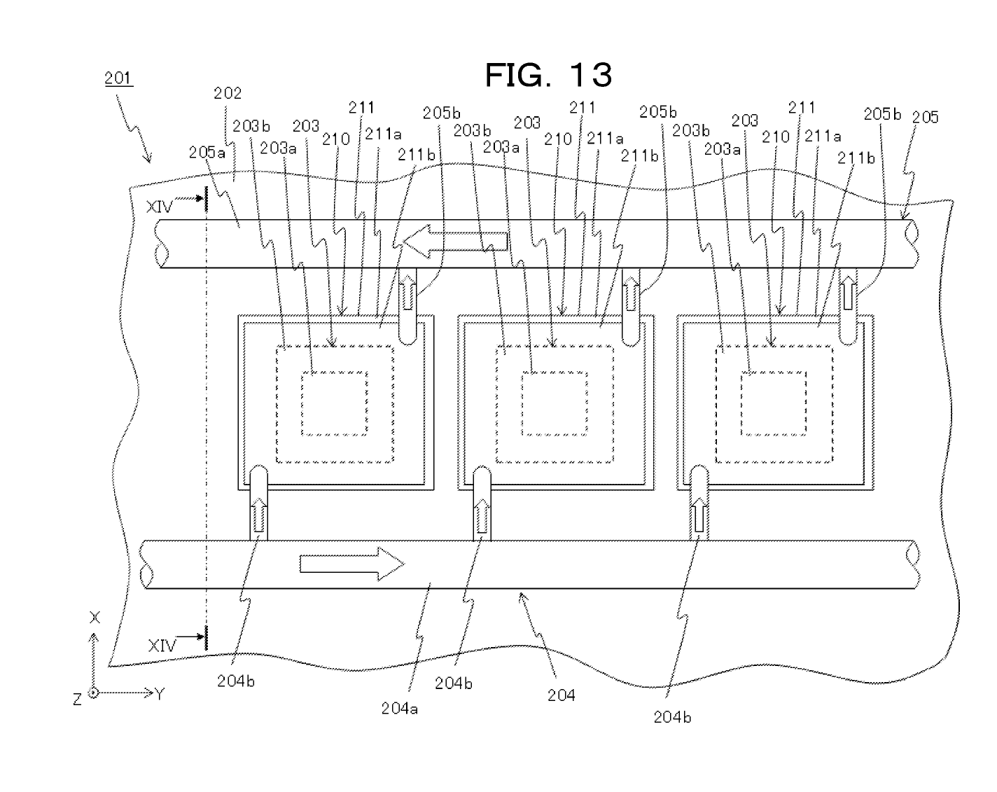

FIG. 13 is a plan view illustrating an electronic device 201 according to a related technology.

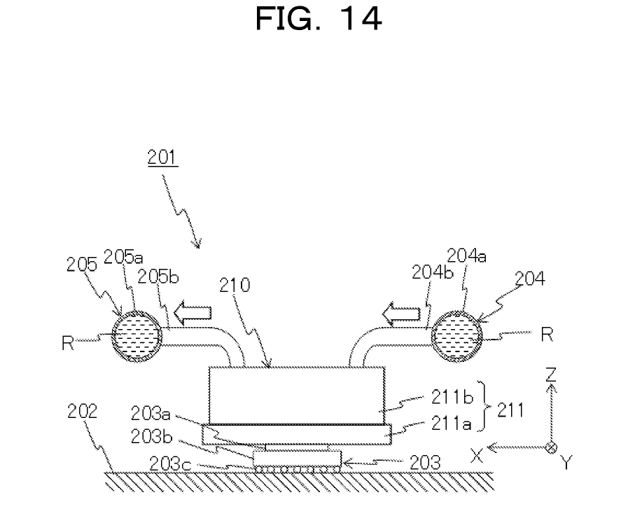

FIG. 14 is a XIV-XIV cross-sectional view of FIG. 13.

The electronic device 201 as illustrated in FIG. 13 includes a base board 202, heater elements 203, supply pipes 204, discharge pipes 205, and coolers 210.

In an example illustrated in FIG. 13, three heater elements 203 are mounted on the base board 202. The base board 202 expands on an XY plane, for example. The base board 202 is an insulated base material having circuit patterns formed thereon. Note that in FIG. 13, a periphery of the base board 202 is depicted by an irregular wavy line (break line) as only a part of the base board 202 is illustrated.

As illustrated in FIG. 14, the heater element 203 has a die 203a, which is a semiconductor chip, a device base board 203b, and a connection 203c, which is a solder. The die 203a is arranged on the device base board 203b. The device base board 203b is mounted in the base board 202 via the connection 203c.

The supply pipe 204 has a main supply pipe 204a and multiple sub-supply pipes 204b branching off from the main supply pipe 204a. The multiple sub-supply pipes 204b are connected to top faces of casings 211 in the different coolers 210, respectively. The casing 211 has a plate-like base 211a and a cover 211b and a refrigerant R illustrated in FIG. 14 flows therein.

Each sub-supply pipe 204b runs the refrigerant R flowing in the main supply pipe 204a, into the casing 211. Note that outlined arrows depicted in FIG. 13 and FIG. 14 represent flow of the refrigerant R. The refrigerant R is liquid.

The discharge pipe 205 has a main discharge pipe 205a and multiple sub-discharge pipes 205b branching off from the main discharge pipe 205a. The multiple sub-discharge pipes 205b are connected to the top faces of the casings 211 in the different coolers 210, respectively. Each sub-discharge pipe 205b runs the refrigerant R discharged from the casing 211, into the main discharge pipe 205a.

The main supply pipe 204a and the main discharge pipe 205a are connected to a heat exchanger which releases heat received by the refrigerant R from the heater element 203. Then, the refrigerant R circulates among the heat exchanger, the supply pipe 204, the cooler 210, and the discharge pipe 205.

In addition, the sub-supply pipe 204b and the sub-discharge pipe 205b are arranged diagonally as illustrated in FIG. 13, or may be arranged on the same center line on the top face of the casing 211 of the cooler 210.

In recent years, with enhancement in computing performance of an electronic device, heat density of a heater element has been increasing. In addition, due to higher integration (introduction of multi-core or multi-chip) of an arithmetic core section and the like, a temperature distribution on a heat releasing surface of a heater element has been becoming uneven.

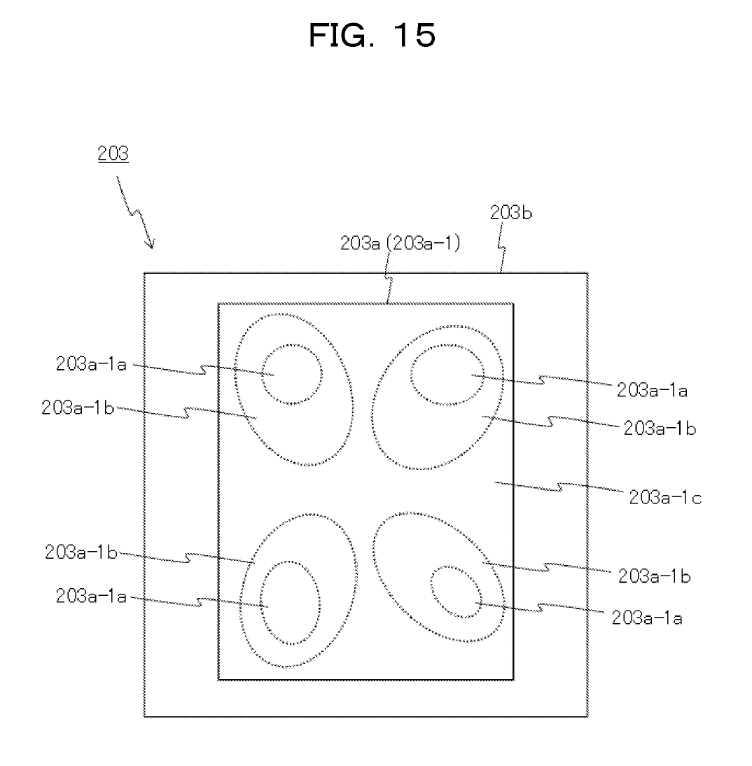

FIG. 15 is a plan view of the heater element 203 for illustrating a temperature distribution on a heat releasing surface 203a-1.

In the above-mentioned heater element 203 as illustrated in FIG. 13 and FIG. 14, the heat releasing surface 203a-1 is located on the die 203a, as illustrated in FIG. 15. The heat releasing surface 203a-1 has the following areas located at four locations, for example: high-temperature areas 203a-1a, medium-temperature areas 203a-1b surrounding a periphery of the high-temperature areas 203a-1a, and low-temperature areas 203a-1c which are areas other than the high-temperature and medium-temperature areas. Note that the high-temperature areas 203a-1a correspond to locations where the arithmetic core section, for example, is placed.

In an example in FIG. 15, a temperature distribution is non-uniform. Thus, when the refrigerant uniformly flows in the cooler 210 in a conventional manner, flow rate becomes excessive in the medium-temperature areas 203a-1b or the low-temperature areas 203a-1c if the flow rate of the refrigerant R is adequate for cooling the high-temperature areas 203a-1a. In addition, when the flow rate of the refrigerant R is adequate for cooling the medium-temperature areas 203a-1B or the low-temperature areas 203a-1c, the flow rate becomes insufficient in the high-temperature areas 203a-1a.

In the following, a cooler and an electronic device according to an embodiment of the disclosure are described.

### First Embodiment

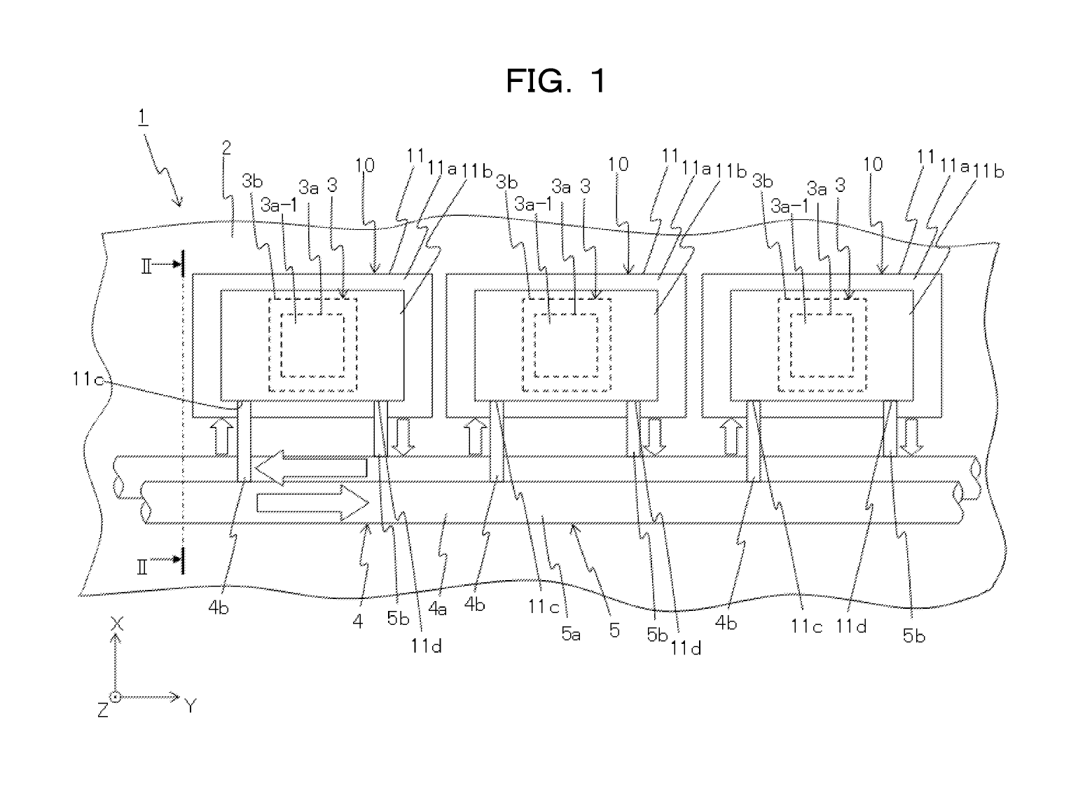

FIG. 1 is a plan view illustrating an electronic device 1 according to a first embodiment.

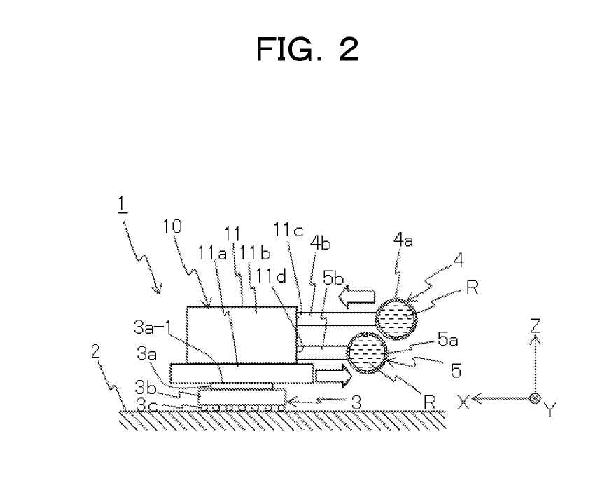

FIG. 2 is a II-II cross-sectional view of FIG. 1.

The electronic device 1 illustrated in FIG. 1 and FIG. 2 includes a base board 2, heater elements 3, supply pipes 4, discharge pipes 5, and coolers 10. The base board 2 is a printed circuit board, for example, used in the electronic device.

The base board 2 is shaped like a plate, for example. In an example illustrated in FIG. 1, three heater elements 3 are mounted on the base board 2. The base board 2 expands on an XY plane, for example. The base board 2 is, for example, an insulated base material on which circuit patterns are formed. Note that in FIG. 1, a periphery of the base board 2 is depicted by an irregular wavy line (break line) as only a part of the base board 2 is illustrated.

The heater element 3 is a central processing unit (CPU), for example. By way of example, as illustrated in FIG. 2, the heater element 3 has a die 3a, which is a semiconductor chip, a device base board 3b, and a connection 3c, which is a solder.

The die 3a is arranged on the device base board 3b. A top face of the die 3a is an example of a heat releasing surface 3a-1. Note that when a base board 2 is vertically placed, the heater element 3 may be arranged not above the base board 2 but beside the base board 2. In addition, the heat releasing surface 3a-1 may be located not on the top face but on the side face of the heater element 3.

The device base board 3b is mounted on the base board 2 via the connection 3c. Similar to the base board 2, the device base board 3b is an insulated base material on which circuit patterns are formed. The heater elements 3 may be a semiconductor chip directly mounted on the base board 2.

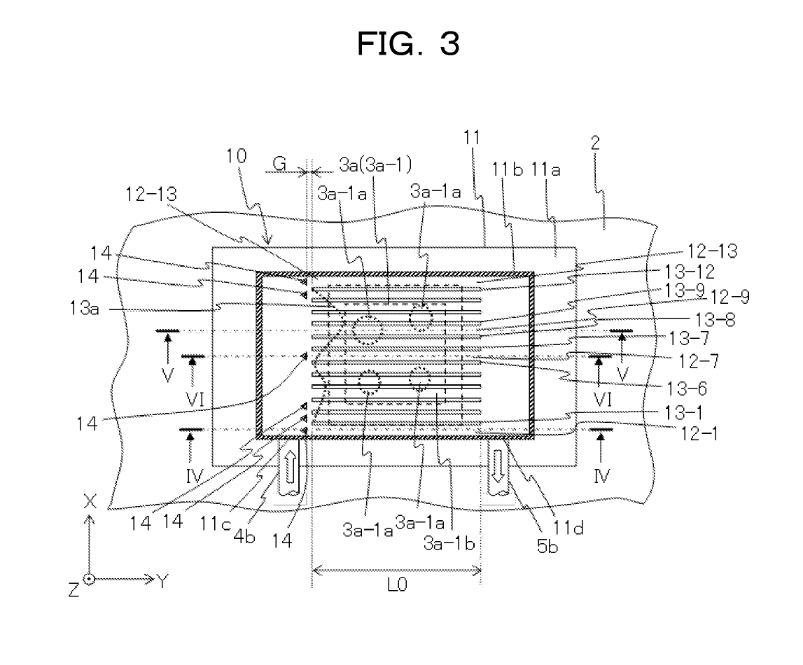

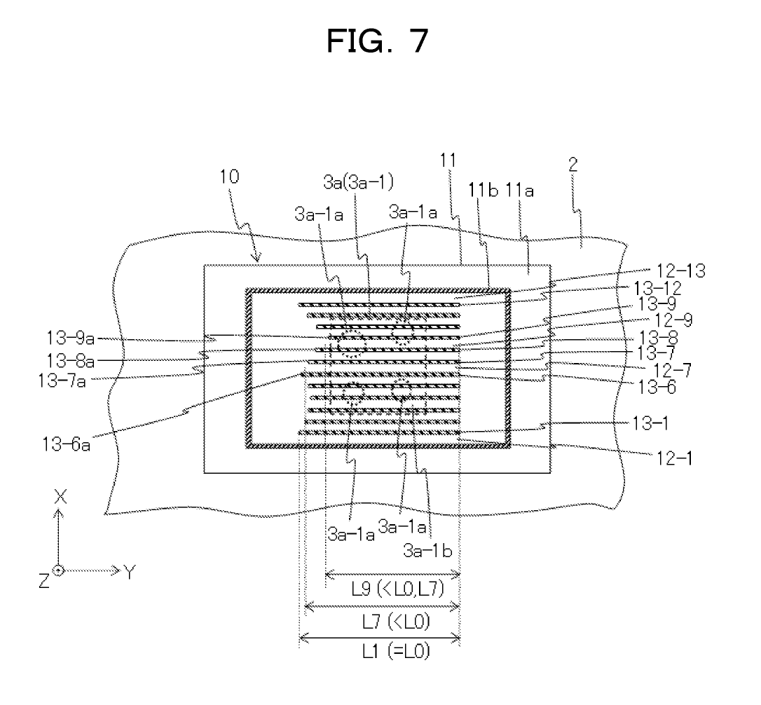

While details are described below, as illustrated by a dot-line in FIG. 3 and FIG. 7, the heat releasing surface 3a-1 has high-temperature areas (hot heat generation area) 3a-1a located on four locations. The high-temperature areas 3a-1a correspond to locations where an arithmetic core section (one example of a core section) is placed. In addition, the high-temperature areas 3a-1a of the heat releasing surface 3a-1 are one example of “a region of higher temperature than an average temperature of the heat releasing surface 3a-1”.

Any area other than the high-temperature areas 3a-1a of the heat releasing surface 3a-1 are low-temperature areas (low heat generation area) 3a-1b which have lower temperature than the high-temperature areas 3a-1a. In addition, the low-temperature areas 3a-1b correspond to any areas excluding the arithmetic core sections, and are one example of “a region of lower temperature than a region of high-temperature of the heat releasing surface 3a-1”.

As illustrated in FIG. 1 and FIG. 2, the supply pipe 4 has a main supply pipe 4a and multiple sub-supply pipes 4b branching off from the main supply pipe 4a. The main supply pipe 4a extends in a direction Y, for example. The sub-supply pipes 4b extend in a direction X, for example. The direction X, the direction Y and a direction Z which is to be described below are orthogonal to each other.

The multiple sub-supply pipes 4b are connected to supply port s11c of casings 11 to be described below, in the different coolers 10, respectively. Each sub-supply pipe 4b runs a refrigerant R, which is illustrated in FIG. 2 and flowing in the main supply pipe 4a, into the supply port 11c of the casing 11. Note that outlined arrows depicted in FIG. 1 and FIG. 2 represent flow of the refrigerant R. The refrigerant R is liquid. However, the refrigerant R may be a mixture in which liquid and gas are mixed.

The discharge pipe 5 has a main discharge pipe 5a and multiple sub-discharge pipes 5b branching from the main discharge pipe 5a. The main discharge pipe 5a extends in the direction Y, for example. The sub-discharge pipes 5b extend in the direction X, for example.

The multiple sub-discharge pipes 5b are connected to discharge ports 11d of the casings 11 in the different coolers 10, respectively. Each sub-discharge pipe 5b runs the refrigerant R, which is discharged from the discharge port 11d of the casing 11, to the main discharge pipe 5a.

The main supply pipe 4a and the main discharge pipe 5a may be connected to a heat exchanger which releases heat received by the refrigerant R from the heater element 3. Then, the refrigerant R may circulate among the heat exchanger, the supply pipe 4, the cooler 10, and the discharge pipe 5. Note that the heat exchanger is arranged inside or outside the electronic device 1.

While details of the casing 11 are described below, the supply port 11c and the discharge port lid of the casing 11 are formed on a same side face (right side face in FIG. 2) of four side faces of the cover 11b of the casing 11. Thus, in comparison with a case where the supply port 11c and the discharge port 11d are formed on the top face or a different side face of a base 11a, a region where the supply pipe 4 and the discharge pipe 5 as illustrated in FIG. 1 and FIG. 2 are arranged may be made smaller in the direction X and the direction Z, for example.

In addition, the main supply pipe 4a and the main discharge pipe 5a extend along the same lateral side (one side on the direction X, for example) of the cooler 10. Thus, in comparison with a case where the main supply pipe 4a and the main discharge pipe 5a extend along both the lateral sides of the cooler 10, a region where the main supply pipe 4 and the main discharge pipe 5 are arranged may be made smaller in the direction X, for example. Note that the main supply pipe 4a and the main discharge pipe 5a do not have to extend right beside the cooler 10, and may extend along the lateral side of the cooler 10 diagonally above the cooler 10. As such, the lateral side of the cooler 10 is a part excluding a part right above and right under the cooler 10.

The sub-supply pipes 4b and the sub-discharge pipes 5b are located at different height. In addition, the sub-supply pipes 4b and the sub-discharge pipes 5b have different length. This may reduce interference with the main supply pipe 4a and the main discharge pipe 5a. Note that in the example illustrated in FIG. 2, the supply port 11c is located upper than the discharge port 11d, and the sub-supply pipes 4b are longer than the sub-discharge pipes 5b.

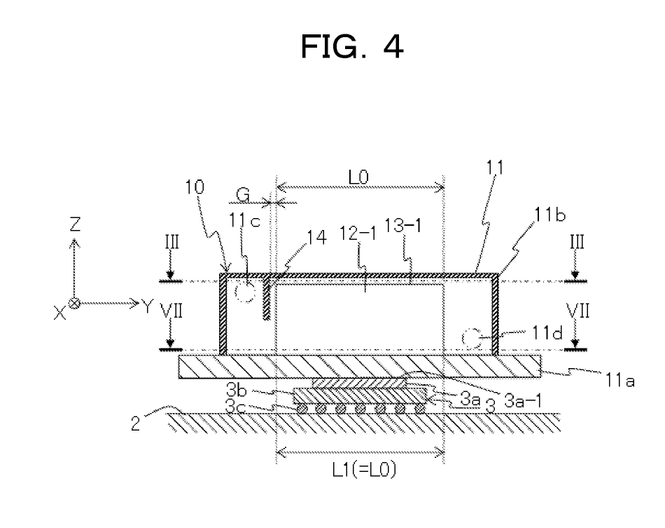

FIG. 3 is a cross-sectional view (III-III cross-sectional view of FIG. 4) illustrating an internal structure of the cooler 10 according to the first embodiment.

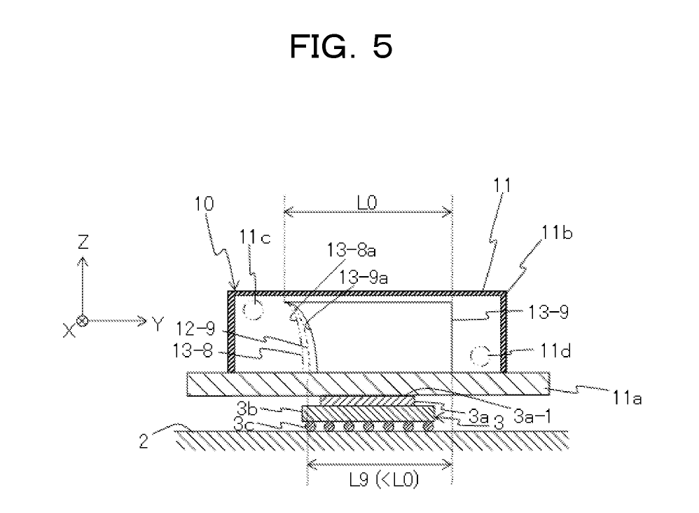

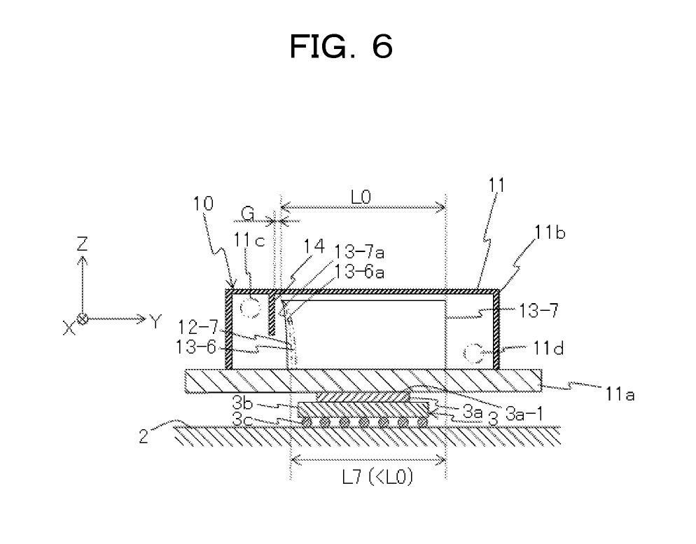

FIG. 4, FIG. 5 and FIG. 6 are a IV-IV cross-sectional view, a V-V cross-sectional view, and a VI-VI cross-sectional view of FIG. 3.

FIG. 7 is a VII-VII cross-sectional view of FIG. 4.

As illustrated in FIG. 3 to FIG. 7, the cooler 10 includes a casing 11, multiple flow channels 12 (12-1 to 12-13), multiple fins (13-1 to 13-12), and multiple limiting sections 14. The cooler 10 is arranged on a heater element 3. Note that when a base board 2 is vertically placed, the cooler 10 may be arranged not above the heater element 3 but beside the heater element 3. By way of example only, the casing 11 has a base 11a and a cover 11b.

The base 11a is arranged on a heat releasing surface 3a-1 of a die 3a of the heater element 3 with heat releasing grease or a heat releasing sheet sandwiched therebetween. Accordingly, the casing 11 is arranged opposed to the heat releasing surface 3a-1. The base 11a is shaped like a plate, for example. In addition, the base 11a expands on an XY plane, for example. It is desirable that the base 11a is made of a material, such as metal, having good heat conductance.

The cover 11b is shaped like a box whose base side is open, so that a refrigerant R flows into a space with the base 11a. As described above, the supply port 11c and the discharge port lid are formed on the side face of the cover 11b. Note that the supply port 11c and the discharge port 11d do not actually appear in FIG. 4 to FIG. 6 as they are located in front of each section line of FIG. 3. Thus, the supply port 11c and the discharge port lid are illustrated by the two-dot chain line (imaginary line) in FIG. 4 to FIG. 6.

Partitioned by the plate-like fins 13, for example, flow channels 12 are provided in the casing 11. In examples as illustrated in FIG. 3 and FIG. 7, thirteen flow channels 12 are provided (12-1, . . . , 12-13) and twelve fins 13 (13-1, . . . , 13-12) are provided.

The fins 13 are arranged on a YZ plane, for example. Heat generated by the heater element 3 is conducted to the fins 13 via the base 11a. Thus, it is desirable that at least some fins 13 are formed above the heat releasing surface 3a-1 of the heater element 3.

Similar to the material of the base 11a, it is desirable that the fins 13 are made of a material, such as metal, having good het conductance. The fins 13 are integrally formed with the base 11a of the casing 11, for example.

Note that the flow channels 12 may be pores formed on a block-like member, for example, rather than being partitioned by the fins 13.

As illustrated in FIG. 5 to FIG. 7, concaves 13-a (13-6a, 13-7a, 13-8a, 13-9a and the like) are formed in the fins 13 other than the fins 13-1, 13-12 on both ends, for example.

The concaves 13a are formed on the end (leftmost end in the example illustrated in FIG. 7) of the fins 13 on the upstream side in a flow direction (direction Y) of the refrigerant R. Note that the concaves 13a may be formed on the end on the downstream side of the flow direction (direction Y) of the refrigerant R. In FIG. 3, one dotted line marked by the sign 13a depicts positions of the upstream-side ends formed by the concaves 13a at the lower ends of the respective fins 13.

The concaves 13a are such formed that length of the fins 13 in the direction Y gradually decreases from the upper end to the lower end, which is a desirable example. Note that the case where the length of the fins 13 in the direction Y gradually decreases also includes a case where the length in the direction Y increases in some of concave-convex parts since end faces of the concaves 13a present a concave-convex shape (saw-toothed shape, for example). Here, the lower-end side (lower end) of the flow channels 12 and the fins 13 is one example of “the one-end side (one end)” which is the heat releasing surface side 3a-1 in the direction Z orthogonal to the heat releasing surface 3a-1. In addition, the upper-end side (upper end) of the flow channels 12 and the fins 13 is one example of “the other-end side (other end)” which is the opposite side to the heat releasing surface 3a-1 in the direction Z orthogonal to the heat releasing surface 3a-1.

As illustrated in FIG. 3, the length in the direction Y of the respective fins 13 at the upper end is same length of L0. However, the length in the direction Y of the respective fins 13 at the upper end does not have to be identical to each other.

As illustrated in FIG. 4, no concave 13a is formed on the fin 13-1 which is one of the fins 13-1 and 13-2 on both ends as illustrated in FIG. 3. Then, the fin 13-1 is shaped like a rectangular plate, for example. Thus, length in the direction Y of the fin 13-1 is L0, irrespective of a position in a height direction. Note that no concave 13a is formed in the other fin 13-12 of the fins 13-1, 13-12 on both ends, either, as illustrated in FIG. 3. Then, the fin 13-12 is shaped like a rectangular-plate, for example. Thus, length in the direction Y of the fin 13-12 is also L0, irrespective of a position in the height direction.

Flow channel length (that is, a length in the flow direction (direction Y) of the refrigerant R) of the flow channels 12-1, 12-13 between the casing 11 and the fins 13-1, 13-12 on both ends, as illustrated in FIG. 3, may be considered identical to the length L0 in the direction Y of the fins 13-1, 13-12. Then, since no concave 13a is formed in the fins 13-1, 13-12 on both ends, the flow channel length of the flow channels 12-1, 12-13 on both ends is L1 (L=0) in their entire area irrespective of positions in the height direction, as illustrated in FIG. 4.

As illustrated in FIG. 3, the flow channel 12-9 opposed to the high-temperature area 3a-1a of the heat releasing surface 3a-1 is located between the two fins 13-8 and 13-9 which are also illustrated in FIG. 5. Here, the flow channel 12-9 illustrated in FIG. 5 is one example of a “first flow channel” and opposed to the arithmetic core section. Note that the fin 13-8 in front of the V-V section line in FIG. 3, which does not appear in FIG. 5, is depicted by a two-dot chain line (imaginary line).

As illustrated in FIG. 7, size of the concaves 13a varies. Thus, as illustrated in FIG. 5, it is believed that the flow channel 12-9 between the two fins 13-8 and 13-9 at each height is located in a range from a center position between the upstream-side ends to a center position between the downstream-side ends of the two fins 13-8 and 13-9. In FIG. 5, a dash line depicts the flow channel 12-9.

Since the above-mentioned concaves 13-8a, 13-9a are formed in the fins 13-8, 13-9 as illustrated in FIG. 5, the flow channel length of the flow channel 12-9 is shorter on the lower-end side than on the upper-end side (L9<L0). In addition, the flow channel length of the flow channel 12-9 gradually decreases from the upper end (L0) to the lower end (L9).

Here, let us consider a case where the flow channel length of the flow channel 12-9 at the “lower end” is equal to or longer than that at the “upper end” (such for example as a case where the upper-end flow channel length is made locally shorter) unlike the example illustrated in FIG. 5. Also in this case, if the average of the flow channel length of the lower half in the height direction of the flow channel 12-9 is shorter than the average of the flow channel length of the upper half, the flow channel length on the lower-end “side” is regarded as shorter than the flow channel length on the upper-end “side”.

As illustrated in FIG. 5, the flow channel length of the flow channel 12-9 gradually decreases in a continuous manner from the upper end (L0) to the lower end (L9), the flow channel length of the flow channel 12-9 may gradually decrease in a discontinued manner. In addition, even if the flow channel length of the flow channel 12-9 has a part that becomes long locally from the upper end (L0) to the lower end (L9), the flow channel length of the flow channel 12-9 is considered to gradually decrease if other parts gradually decrease.

As illustrated in FIG. 5, degree of the flow channel length of the flow channel 12-9 becoming shorter is reduced as the flow channel length of the flow channel 12-9 is closer to the lower end (L9) from the upper end (L0), which is simply by way of example, though. Accordingly, a line connecting the upstream-side ends (left ends in the example illustrated in FIG. 5) in the flow channel 12-9 is curved.

As illustrated in FIG. 3, the flow channel 12-7 opposed only to the low-temperature area 3a-1b of the heat releasing surface 3a-1b is located between the two fins 13-16 and 13-7 which are also illustrated in FIG. 6. Here, the flow channel 12-7 illustrated in FIG. 6 is one example of a “second flow channel” and opposed to parts excluding the arithmetic core section. Note that the fin 13-6 in front of the VI-VI section line in FIG. 3, which does not appear in FIG. 6, is depicted by a two-dot chain line (imaginary line). In addition, in FIG. 6, a dash line depicts the flow channel 12-7.

As illustrated in FIG. 6, since the above-mentioned concaves 13-6a, 13-7a are formed in the fins 13-6, 13-7, the flow channel length of the flow channel 12-7 is shorter on the lower-end side than on the upper-end side (L7<L0).

Similar to the flow channel length of the flow channel 12-9 illustrated in FIG. 5, the flow channel length of the flow channel 12-7 illustrated in FIG. 6 gradually decreases from the upper end (L0) to the lower end (L7). In addition, similar to the flow channel length of the flow channel 12-9, degree of the flow channel length of the flow channel 12-7 becoming shorter is reduced as the flow channel length of the flow channel 12-7 is closer to the lower end (L7) from the upper end (L0).

In addition, as illustrated in FIG. 7, it is desirable that the flow channel length on the lower-end side (L9) of the flow channel 12-9 (example of the first flow channel) illustrated in FIG. 5 is shorter than the flow channel length on the lower-end side (L7) of the flow channel 12-7 (example of the second flow channel) illustrated in FIG. 6 (L9<L7).

The limiting sections 14 as illustrated in FIG. 3, FIG. 4, and FIG. 6 limit flow rate of the refrigerant R flowing to the upper-end sides of the flow channel 12-7 (one example of the second flow channel) and the flow channels 12-1, 12-13, and the like which are not opposed to the heat releasing surface 3a-1. The limiting sections 14 limit the flow rate of the refrigerant R, for example, by blocking the flow of the refrigerant R.

Note that the limiting sections 14 may limit the flow rate of the refrigerant R flowing at least in a part of the upper-half, which is the upper end sides of the flow channels 12-1, 12-7, 12-13. However, it is desirable that the limiting sections 14 limit the flow rate of the refrigerant R in a part including the upper ends of the flow channels 12-1, 12-7, 12-13.

The limiting sections 14 may be located with a gap G from the flow channels 12-1, 12-7, and 12-13 in the flow direction (direction Y) of the refrigerant R. In the examples of FIG. 3, FIG. 4, and FIG. 6, the limiting sections 14 are located upstream of the flow channels 12-1, 12-7, 12-13 in the flow direction (direction Y) of the refrigerant R. As illustrated in FIG. 4 and FIG. 6, on the upstream side of the flow channels 12-1, 12-7, 12-13, the limiting sections 14 are opposed to these flow channels from the upper ends to a part near the center in the height direction.

The limiting sections 14 may be integrally formed with the casing 11. In the example illustrated in FIG. 3, FIG. 4, and FIG. 6, the limiting sections 14 are integrally formed with the cover 11b of the casing 11. Note that the limiting sections 14 may be integrally provided with the fins 13 or fixed to the casing 11 or the fins 13.

A shape of the limiting sections 14 is a triangular prism whose cross-section on the XY plane illustrated in FIG. 3 is triangle shaped. The triangle shaped limiting sections 14 have one apex of the triangle shaped cross section on the XY plane located on the upstream side in the flow direction of the refrigerant R (direction Y), while the other two apexes are located on the downstream side. The shape of the limiting sections 14 may be a quadratic prism, a cylinder, or other shape.

In addition, the limiting sections 14 may be provided in the flow channels 12-1, 12-7, 12-13. In addition, while the limiting sections 14 may be provided so as to completely block a part of the flow channels 12-1, 12-7, 12-13, it is desirable that the limiting sections 14 do not completely block because heat conductance to the refrigerant R from the fins 13 is obstructed.

In the first embodiment which has been described so far, the flow channel 12-9 (one example of the first flow channel) is opposed to the high-temperature areas 3a-1a (arithmetic core section). In addition, the flow channel length of the flow channel 12-9 is shorter on the lower-end side (one example of the one-end side) which is the heat releasing surface 3a-1 side in the direction (direction Z) orthogonal to the heat releasing surface 3a-1 than on the upper-end side (one example of the other-end side) (L9<L0).

Thus, on the side of high-temperature areas 3a-1a, which is the lower-end side of the flow channel 12-9 where the flow channel length is short, pressure loss of the refrigerant R proportional to the flow channel length may be reduced. Accordingly, a flow velocity of the refrigerant R on the side of the high-temperature areas 3a-1a of the flow channel 12-9 where the flow channel length is made short may be accelerated by controlling a reduction in the flow velocity due to the pressure loss. This may increase the flow rate of the refrigerant R. In addition, on the upper-end side of the flow channel 12-9, by securing longer flow channel length than on the lower-end side, release of heat generated from the heater element 3 may be facilitated through heat conduction and the like to the refrigerant R by way of members (fins 13) which partition the flow channel 12-9. Therefore, the high-temperature areas 3a-1a may be efficiently cooled. Thus, according to the first embodiment, the cooling efficiency of the heater element 3 may be increased.

In addition, in the first embodiment, the flow channel length on the lower-end side of the flow channel 12-9 (one example of the first flow channel) is shorter than the flow channel length on the lower-end side of the flow channel 12-7 which is opposed only to the low-temperature areas 3a-1b (areas excluding the arithmetic core section) (L9<L7). Thus, the flow rate of the refrigerant R may be increased as described above on the lower-end side of the flow channel 12-9 opposed to the high-temperature areas 3a-1a than on the lower-end side of the flow channel 12-7 opposed to the low-temperature areas 3a-1b. In addition, release of the heat generated by the heater element 3 may be facilitated by securing longer flow channel length on the lower-end side of the flow channel 12-7 opposed to the low-temperature areas 3a-1b than on the lower-end side of the flow channel 12-9 opposed to the high-temperature areas 3a-1a.

In addition, in the first embodiment, the limiting sections 14 limit the flow rate of the refrigerant R flowing on the upper-end side of the flow channel 12-7 (one example of the second flow channel). Accordingly, it is possible to cause the refrigerant R to flow easily on the lower-end side of the flow channel 12-7 opposed to the low-temperature areas 3a-1b, as well as the lower-end side and the upper-end side of the flow channel 12-9 (one example of the first flow channel) opposed to the high-temperature areas 3a-1a.

In addition, in the first embodiment, the limiting sections 14 are located with a gap G from the flow channel 12-7 (one example of the second flow channel) in the flow direction of the refrigerant R (direction Y). Thus, the limiting sections 14 may limit the flow rate of the refrigerant R, while controlling interference with the members (fins 13), which partition the flow channel 12-7, and the limiting sections 14.

In addition, in the first embodiment, the limiting sections 14 are integrally provided with the casing 11 (cover 11b). Thus, the limiting sections 14 may be arranged without increasing the number of components.

In addition, in the first embodiment, the flow channel length L0 of the flow channel 12-9 (example of the first flow channel) at the upper end is same as the flow channel length L0 of the flow channel 12-7 (one example of the second flow channel) at the upper end. Thus, the coolers 10 may have a simple configuration.

In addition, in the first embodiment, the flow channel length of the flow length 12-7 (one example of the second flow channel) gradually decreases from the upper end (L0) to the lower end (L7). Thus, the flow rate of the refrigerant R may be increased as the refrigerant R is closer to the lower end from the upper end of the flow channel 12-7.

In addition, in the first embodiment, the flow channel length of the flow channel 12-9 (one example of the first flow channel) gradually decreases from the upper end (L0) to the lower end (L9). Thus, the flow rate of the refrigerant R may be increased as the refrigerant R is closer to the lower end from the upper end of the flow channel 12-9.

In addition, in the first embodiment, the plate-like fins 13 partition the flow channels 12 such as the first flow channel 12-9. Thus, the heat generated from the heater element 3 may be heat-conducted to the refrigerant R flowing in the flow channels 12 by way of the fins 13.

In addition, in the first embodiment, the supply port 11c and the discharge port 11d of the casing 11 are formed on the same side face of the casing 11 (base 11a). Thus, in comparison with a case where the support port 11c and the discharge port 11d are formed on the top face or a different side face of the base 11a, a region where the supply pipes 4 and the discharge pipes 5 are arranged may be made smaller in the direction X and the direction Z, for example.

In addition, in the first embodiment, the main supply pipe 4a and the main discharge pipe 5a extend along the same lateral side (one side in the direction X, for example) of the cooler 10. Thus, in comparison with a case where the main supply pipe 4a and the main discharge pipe 5a extend along both the lateral sides of the cooler 10, a region where the main supply pipe 4 and the main discharge pipe 5 are arranged may be made smaller in the direction X, for example.

### Second Embodiment

In the second embodiment, matters different from the first embodiment are mainly described.

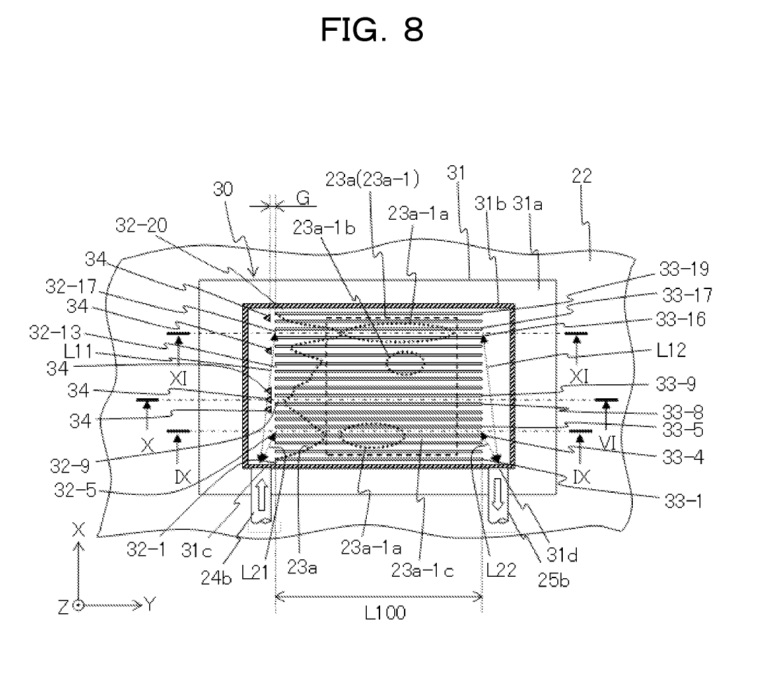

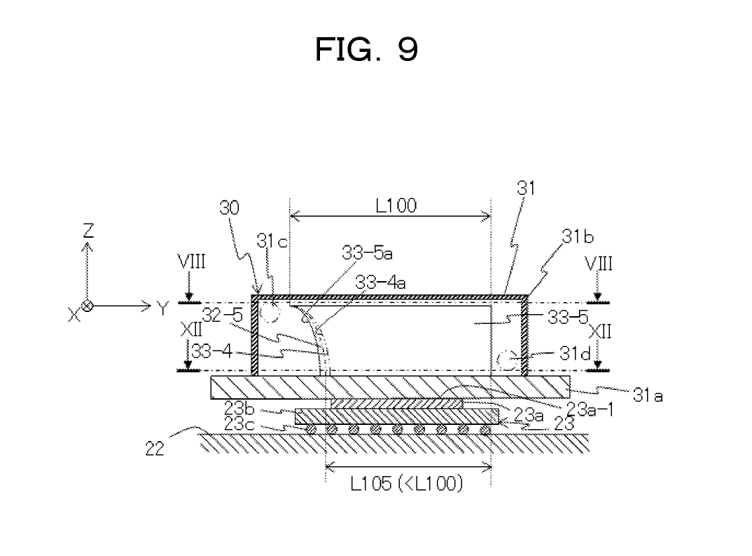

FIG. 8 is a cross-sectional view (VIII-VIII cross-sectional view of FIG. 9) illustrating an internal structure of a cooler 30 according to the second embodiment.

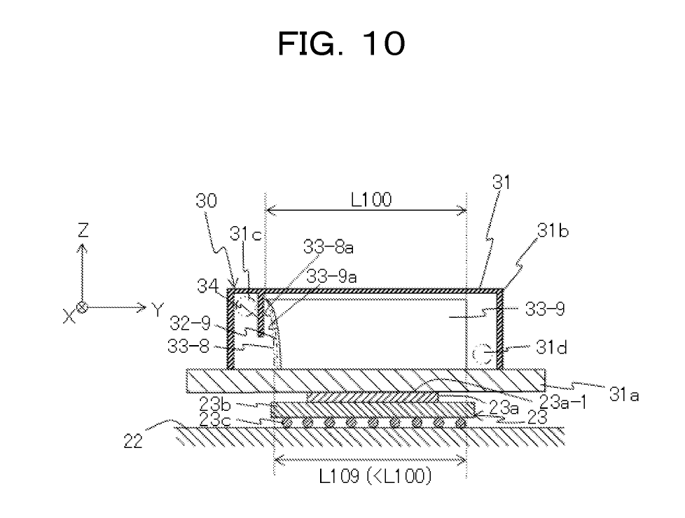

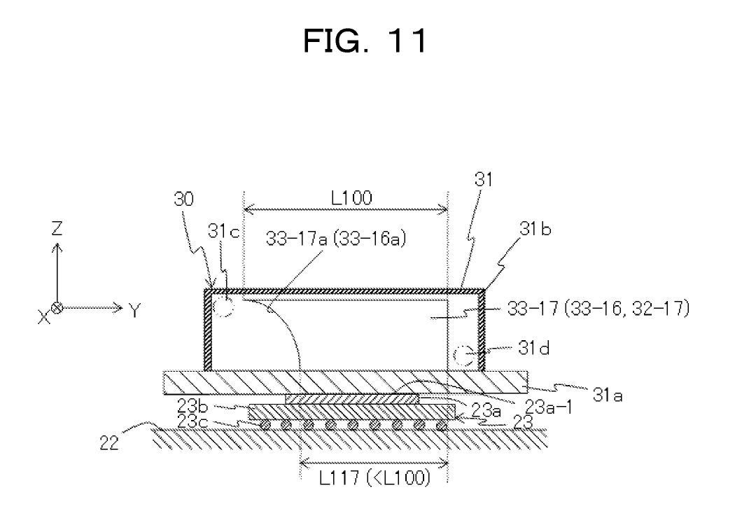

FIG. 9, FIG. 10, and FIG. 11 are a IX-IX cross-sectional view, a X-X cross-sectional view, and a XI-XI cross sectional view of FIG. 8.

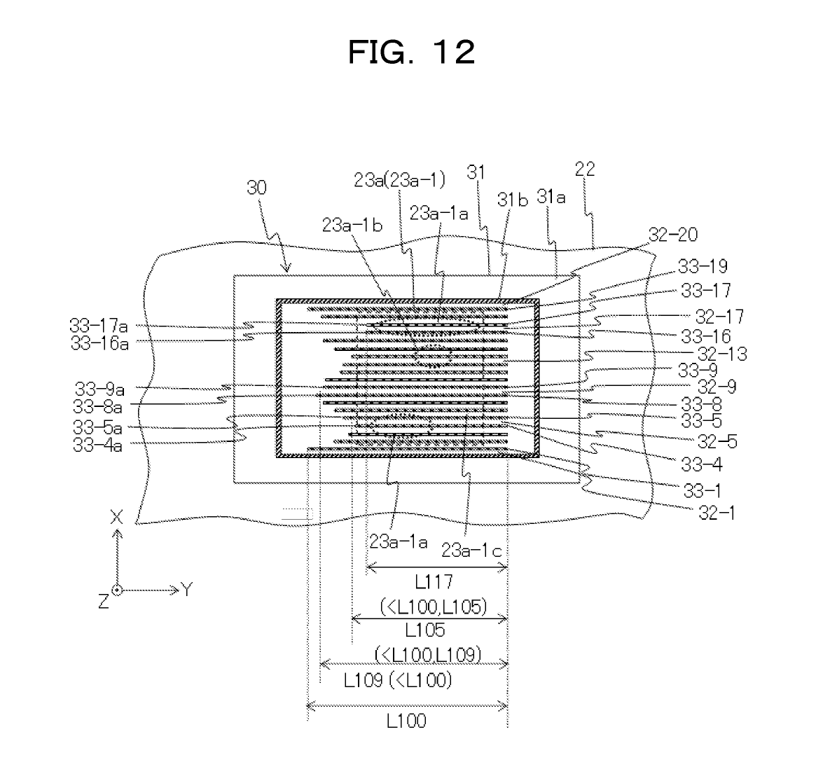

FIG. 12 is a XII-XII cross-sectional view of FIG. 9.

As illustrated in FIG. 9 to FIG. 11, a heater element 23 mounted on a base board 22 has a die 23a which is a semiconductor chip, a device base board 23b, and connections 23c which are a solder, which is by way of example, though. A top face of the die 23a is one example of a heat releasing surface 23a-1.

While details are described below, as illustrated by a dot-line in FIG. 8 and FIG. 12, the heat releasing surface 23a-1 has high-temperature areas (high heat generation area) 23a-1a located at two locations, for example. Note that the high-temperature areas 23a-1a correspond to an arithmetic core section (one example of a core section), and are one example of a “region of higher temperature than an average temperature of the heat releasing surface 23a-1” of the heat releasing surface 23a-1.

In addition, as illustrated by the dot-line in FIG. 8 and FIG. 12, the heat releasing surface 23a-1 has a medium-temperature area (medium heat generation area) 23a-1b located at one location, for example. The medium-temperature area 23a-1b corresponds to the arithmetic core section, and has lower temperature than the high-temperature areas 23a-1a and higher temperature than a low-temperature area (low heat generation area) 23a-1c to be described below. The medium-temperature area 23a-1b may be equal to or higher than or equal to or lower than the average temperature of the heat releasing surface 23a-1.

Of the heat releasing surface 23a-1, any area other than the high-temperature areas 23a-1a and the medium-temperature area 23a-1b is a low-temperature area 23a-1c which has lower temperature than the high-temperature areas 23a-1a and the medium-temperature area 23a-1b. In addition, the low-temperature area 23a-1c corresponds to any area excluding the arithmetic core section and is one example of a “region of lower temperature than a region of high temperature of the heat releasing surface 23a-1”.

As illustrated in FIG. 8 and FIG. 12, also in the second embodiment, sub-supply pipes 24b and the sub-discharge pipes 25b are formed on a same side face out of four side faces of a cover 31b in a casing 31 of a cooler 30.

As illustrated in FIG. 8 to FIG. 12, the cooler 30 includes the casing 31, a multiple flow channels 32 (32-1 to 32-20), multiple fins 33 (33-1 to 33-19), and multiple limiting sections 34.

Also in the second embodiment, the casing 31 has a base 31a and the cover 31b.

Partitioned by the plate-like fins 33, for example, the flow channels 32 are provided in the casing 31. In an example illustrated in FIG. 8 and FIG. 12, twenty flow channels 32 are provided (32-1, . . . , 32-20) and nineteen fins 33 are provided (33-1, . . . , 33-19).

As illustrated in FIG. 8 to FIG. 12, concaves 33a (33-4a, 33-5a, 33-8a, 33-9, a 33-16a, 33-17a and the like) are formed on the fins 33 other than the fins 33-1, 33-19 on both ends, for example.

The concaves 33a are formed on the upstream-side ends (left ends in the example illustrated in FIG. 12) of the fins 33 in a flow direction (direction Y) of a refrigerant R. Note that the concaves 33a may be formed on the downstream-side ends in the flow direction of the refrigerant R (direction Y). In FIG. 8, one dot-line marked by a sign 33a depicts positions of the upstream-side ends formed by the concaves 33a at lower ends of the respective fins 33.

The concaves 33a are such formed that length of the fins 33 in the direction Y gradually decreases from the upper end to the lower end, which is one desirable example. Here, the lower-end side (lower end) of the flow channels 32 and the fins 33 is one example of “the one-end side (one end)” which is the heat releasing surface side 23a-1 in the direction Z orthogonal to the heat releasing surface 23a-1. In addition, the upper-end side (upper end) of the flow channels 32 and the fins 33 is one example of “the other-end side (other end)” which is the opposite side to the heat releasing surface 23a-1 in the direction Z orthogonal to the heat releasing surface 23a-1.

As illustrated in FIG. 8, the length in the direction Y of the respective fins 33 at the upper end is same length of L0. However, the length in the direction Y of the respective fins 33 at the upper end does not have to be of same length.

As illustrated in FIG. 8, a flow channel 32-5 opposed to the high-temperature areas 23a-1a of the heat releasing surface 23a-1 is located between two fins 33-4 and 33-5 which are also illustrated in FIG. 9. Here, the flow channel 32-5 illustrated in FIG. 9 is one example of a “first flow channel” and opposed to the arithmetic core section.

As illustrated in FIG. 9, since the above-mentioned concaves 33-4a, 33-5a are formed in the fins 33-4, 33-5, the flow channel length of the flow channel 32-5 is shorter on the lower-end side than on the upper-end side (L105<L100). In addition, the flow channel length of the flow channel 32-5 gradually decreases from the upper end (L100) to the lower end (L105). Degree of the flow channel length of the flow channel 32-5 becoming shorter is reduced as the flow channel length of the flow channel 32-5 is closer to the lower end (L105) from the upper end (L100), which is simply by way of example, though.

As illustrated in FIG. 8, a flow channel 32-9 which is opposed only to the low-temperature area 23a-1c of the heat releasing surface 23a-1 is located between two fins 33-8 and 33-9 which are also illustrated in FIG. 10. Here, the flow channel 32-9 illustrated in FIG. 10 is one example of a “second flow channel” and opposed to parts excluding the arithmetic core section.

As illustrated in FIG. 10, since the above-mentioned concaves 33-8a, 33-9a are formed in the fins 33-8, 33-9, the flow channel length of the flow channel 32-9 is shorter on the lower-end side than on the upper-end side (L109<L100).

Similar to the flow channel length of the flow channel 32-5 illustrated in FIG. 9, the flow channel length of the flow channel 32-9 illustrated in FIG. 10 gradually decreases from the upper end (L100) to the lower end (L109). In addition, similar to the flow channel length of the flow channel 32-5, degree of the flow channel length of the flow channel 32-9 becoming shorter is reduced as the flow channel length of the flow channel 32-9 is closer to the lower end (L109) from the upper end (L100).

It is desirable that the flow channel length on the lower-end side of the flow channel 32-5 (one example of the first flow channel) illustrated in FIG. 9 is shorter than the flow channel length on the lower-end side of the flow channel 32-9 (one example of the second flow channel) illustrated in FIG. 10 (L105<L109). In addition, it is desirable that the flow channel length on the lower-end side of the flow channel 32-13 which is opposed to the medium-temperature area 23a-1b and illustrated in FIG. 8 and FIG. 12 is longer than the flow channel length on the lower-end side of the flow channel 32-5 and shorter than the flow channel length on the lower-end side of the flow channel 32-9.

As illustrated in FIG. 8, the flow channel 32-17 is opposed to other area different from one area to which the above-mentioned flow channel 32-5 is opposed, of the two high-temperature areas 23a-1a in the heat releasing surface 23a-1. The flow channel 32-17 is located between two fins 33-16 and 33-17 which are also illustrated in FIG. 11. Note that concaves 33-16a, 33-17a of a same shape are formed at a same position in the two fins 33-16, 33-17. Thus, the fin 33-16 has a same shape as the fin 33-17. Therefore, in FIG. 11, the fin 33-16 and the flow channel 32-17 are assigned the bracketed signs of the fin 33-17.

The flow channel 32-17 may be opposed to the high-temperature areas 23a-1a which are same as (integrally with, for example) the high-temperature areas 23a-1a to which the flow channel 32-5 is opposed. In addition, the high-temperature areas 23a-1a to which the flow channel 32-5 is opposed and the high-temperature areas 23a-1a to which the flow channel 32-17 is opposed may have same or different temperature.

Here, the flow channel 32-17 illustrated in FIG. 11 is one example of a “third channel” and opposed to the arithmetic core section. As illustrated in FIG. 8, length from a supply port 31c of the casing 31 to the flow channel 32-17 is L11, and length from the flow channel 32-17 to a discharge port 31d is L12. A sum of the length L11 and L12 is larger than a sum of length L21 from the supply port 31c to the flow channel 32-15 (one example of the first channel) and length L2 from the flow channel 32-15 to the discharge port 31d.

As illustrated in FIG. 11, since the above-mentioned concaves 33-16a, 33-17a are formed in the fins 33-16, 33-17, the flow channel length of the flow channel 32-17 is shorter on the lower-end side than on the upper-end side (L117<L100). In addition, the flow channel length of the flow channel 32-17 gradually decreases from the upper end (L100) to the lower end (L117). Degree of the flow channel length of the flow channel 32-17 becoming shorter is reduced as the flow channel length of the flow channel 32-17 is closer to the lower end (L117) from the upper end (L100), which is simply by way of example, though.

In addition, the flow channel length on the lower-end side of the flow channel 32-17, which is one example of the third channel, is shorter than the flow channel length on the lower-end side of the flow channel 32-5 which is one example of the first channel (L117<L105).

The limiting sections 34 illustrated in FIG. 8 and FIG. 10 limit flow rate of the refrigerant R flowing to the upper-end side in some of the flow channels 32 such as the flow channel 32-9 (one example of the second channel). For example, the limiting section 34 is located with a gap G from the flow channel 32-9 and the like in the flow direction (direction Y) of the refrigerant R.

In the second embodiment as described above, similar effects may be achieved for the configuration similar to the first embodiment as described above.

In addition, in the second embodiment, the flow channel 32-17, which is one example of the third channel, is opposed to the arithmetic core section which is different from or same as the flow channel 32-5, which is one example of the first channel. In addition, as illustrated in FIG. 8, the flow channel 32-17 has length of L11 from the supply port 31c of the casing 31 and of L12 to the discharge port 31d. A sum of the length L11 and L12 is larger than a sum of the length L21 from the supply port 31c and of L22 to the discharge port 31d in the flow channel 32-5. Then, the flow channel length on the lower-end side of the flow channel 32-17 is shorter than the flow channel length on the lower-end side of the flow channel 32-5 (L117<L105). Accordingly, the flow rate of the refrigerant R may be increased in the flow channel 32-17 in which the flow rate of the refrigerant R decreases due to pressure loss and the like attributable to a distance from the supply port 31c and the discharge port 31d of the casing 31.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, ad alterations could be made hereto without departing from the spirit and scope of the invention.

What is claimed is:

1. A cooler comprising:
a casing arranged opposed to a heat releasing surface of a heater element; and
a first flow channel which is provided in the casing and through which a refrigerant flows, wherein
in a direction orthogonal to the heat releasing surface, a length of the first flow channel on a heat releasing surface side is shorter than a length of the first flow channel on the opposite side to the heat releasing surface.

2. The cooler according to claim 1, wherein
the first flow channel is opposed to a core section of the heater element.

3. The cooler according to claim 2, further comprising:
a second flow channel which is provided in the casing and through which the refrigerant flows, wherein
the second flow channel is opposed to a section of the heater element other than the core section, and
in the direction orthogonal to the heat releasing surface, the length of the first flow channel on the heat releasing surface side is shorter than a length of the second flow channel on the heat releasing surface side.

4. The cooler according to claim 3, further comprising:
a limiting section configured to limit flow rate of the refrigerant flowing in the second flow channel on the opposite side to the heat releasing surface side in the direction orthogonal to the heat releasing surface.

5. The cooler according to claim 4, wherein
the limiting section is arranged with a gap from the second flow channel in a flow direction of the refrigerant.

6. The cooler according to claim 4, wherein
the limiting section is integrally provided with the casing.

7. The cooler according to claim 3, wherein
in the direction orthogonal to the heat releasing surface, the length of the first flow channel on the opposite side to the heat releasing surface side is equal to
a length of the second flow channel on the opposite side to the heat releasing surface.

8. The cooler according to claim 3, wherein
the length of the second flow channel gradually decreases to the heat releasing surface side from the opposite side to the heat releasing surface side.

9. The cooler according to claim 1, wherein
the length of the first flow channel gradually decreases to the heat releasing surface side from the opposite side to the heat releasing surface side.

10. The cooler according to claim 1, further comprising:
a plurality of plate-like fins which partition the first flow channel.

11. The cooler according to claim 1, wherein
a supply port and a discharge port of the casing are formed on a same side face of the casing.

12. The cooler according to claim 1, further comprising:
a third flow channel which is provided in the casing and through which the refrigerant flows, wherein
the third flow channel is opposed to the core section of the heater element, and
a sum of length from the supply port of the casing to the third channel and length from the third channel to the discharge port of the casing is larger than a sum of length from the supply port to the first channel and length from the first channel to the discharge port.

13. An electronic device comprising:
a base board;
a heater element mounted on the base board;
a cooler including a casing arranged opposed to a heat releasing surface of the heater element, and a first flow channel which is provided in the casing and through which a refrigerant flows;
a supply pipe configured to supply the refrigerant to a supply port of the casing; and
a discharge pipe configured to discharge the refrigerant from a discharge port of the casing, wherein
a length of the first flow channel is shorter on one end side thereof in a direction orthogonal to the heat releasing surface than on the other end side thereof, the one end side located on a side close to the heat releasing surface side.

14. The electronic device according to claim 13, wherein
the supply pipe includes a first supply pipe and a second supply pipe which branches off from the first supply pipe and is connected to the supply port of the casing,
the discharge pipe includes a first discharge pipe and a second discharge pipes which branches off from the first discharge pipe and is connected to the discharge port of the casing, and
the first supply pipe and the first discharge pipe extend along a same lateral side of the cooler.
